(19) United States
(12) Patent Application Publication
(10) Pub. No.: US 2006/0220191 A1
(43) Pub. Date: Oct. 5, 2006

(54) Electronic package with a stepped-pitch leadframe

(75) Inventor: Lance L. Sundstrom, Pinellas Park, FL (US)

Correspondence Address: HONEYWELL INTERNATIONAL INC., 101 COLUMBIA ROAD, P O BOX 2245, MORRISTOWN, NJ, 07962-2245, US

(73) Assignee: HONEYWELL INTERNATIONAL INC., MORRISTOWN, NJ (US)

(21) Appl. No.: 11/096,823

(22) Filed: Apr. 1, 2005

(51) Int. Cl. H01L 23/495

(52) U.S. Cl. 257/669; 257/670; 257/676

(57) ABSTRACT

A leadframe for an electronic package is provided. The lead frame includes a plurality of leads each having an outer lead bond and an inner lead bond. The plurality of leads are interconnected by a tie bar. The plurality of leads have a first pitch at an exit or attach point for an electronic package and a second, larger pitch at the outer lead bonds.

### BACKGROUND

Almost all electronic devices incorporate one or more integrated circuits (ICs). The term “IC” has been used loosely in the industry to refer to (1) a group of electronic devices diffused into and/or deposited onto a monolithic substrate, (2) the entire monolithic substrate, e.g., a die containing one or more electronic circuits or (3) one or more monolithic circuit substrates housed in a single electronic package. Examples of monolithic circuits include deposited thick and/or thin film materials on a supporting substrate or diffusions into and/or depositions onto a semiconductor wafer. The term “die” usually refers to a single monolithic IC cut from a semiconductor wafer containing many identical or similar monolithic ICs. Most electronic devices incorporate many ICs connected together as part of an electronic system. IC die are typically manufactured en mass on wafers, separated and assembled into electronic packages. A typical electronic package contains one or more IC die. In many systems, multiple packages are mounted on a printed circuit board (PCB) that connects the packages together. Thus, many electronic devices include multiple packages connected together on a PCB.

A typical electronic package includes one or more IC die, a body and possibly a leadframe. Electronic packages with leadframes include dual flat pack (DFP) and quad flat pack (QFP). Each of these electronic packages includes a planar leadframe. The IC die is a portion of a specially manufactured semiconductor wafer that typically contains many ICs. The body is a rigid structure that encloses the IC die/dice and protects it from its environment. The leadframe is a series of electrically conductive leads with inner lead bond and outer lead bond interfaces. The inner lead bond refers to the innermost portion of a lead that attaches to the exterior of the package body or extends into the package to interface directly or indirectly with the IC die/dice. The outer lead bond refers to the outermost portion of a lead that interfaces with the package footprint on a host PCB, e.g., via through-hole or surface mount solder connections. Most electronic packages contain these three basic components, although there are various types of each component.

One common type of planar leadframe is the side-exit leadframe. In the side-exit leadframe, a portion of each lead extends inside the package body and a portion of each lead is outside the package body. Inside the package body, each inner lead bond is electrically connected directly or indirectly, e.g., via bond wires to the IC die/dice. Each lead exits the package body through a side of the body. Outside the package body, each outer lead bond terminates in a form that can be interfaced with an external connection, such as the package footprint on a host PCB.

Another common type of planar leadframe is the external attach leadframe. For the external attach leadframe, the top or bottom outside periphery of the electronic package body includes lead attach pads. Each lead attach pad is electrically connected indirectly to the IC die/dice inside the package. Each inner lead bond is conductively attached to the peripheral lead attach pad, e.g., via a braze. Each outer lead bond terminates in a form that can be interfaced with an external connection, such as the package footprint on a host PCB.

The planar side-exit or external attach leadframe is formed down and attached to the PCB some distance away from its exit/attachment point on the package. This distance determines the amount of lead compliance, which relates to the endurance and reliability of the lead frame connections in the presence of PCB flexure due to acceleration, shock and vibration.

The outer lead bonds of the package's leadframe interface at the package footprint of the host PCB to enable electrical signals to be transferred between the IC die/dice inside the package and other IC die/dice inside other packages of the electronic system. The spacing of the outer lead bonds of the leadframe are matched to the location of surface mount technology (SMT) pads or through holes in the package footprint of the host PCB. These pads or through holes collectively “connections” are typically laid out on a PCB in a regular pattern referred to as the package footprint, with the connections spaced apart at the outer lead bond pitch of the leadframe. The outer lead bond pitch is the uniform spacing of adjacent outer lead bonds of the leadframe.

On packages with side-exit leadframes, the leads exit the body at an exit pitch that is equal to the outer lead bond pitch. On these packages, each side of the body with leads is typically close to the connections in the package footprint of the host PCB. Often, the side of the body with leads is parallel to a row of external connections in the package footprint of the host PCB. Each lead exits the body perpendicular to the side of the body. Each lead is the same length. Each lead travels a relatively short distance out from the package body and down to its connection in the package footprint of the host PCB.

On packages with external attach leadframes, the lead attach pads are spaced at a pad pitch that is equal to the outer lead bond pitch. On these packages, each side of the body with leads is also typically close to the external connections in the package footprint of the host PCB. Again, the side of the body with leads is often parallel to a row of connections in the package footprint of the host PCB. Each lead attaches to a lead attach pad and crosses the side of the body perpendicular to the side of the body. Each lead is the same length. Each lead travels a relatively short distance out from the lead attach pad, away from the package body and down to its corresponding connection in the package footprint on the host PCB.

Although the electronic packages described above have worked in many applications, these package designs still experience problems. One common problem is lead failure due to repeated lead flexure from acceleration, shock and/or vibration. Many electronic devices experience acceleration, shock and/or vibration in commercial, industrial, automotive, military and space applications. When an electronic device experiences acceleration, shock and/or vibration, the PCBs inside the device often flex and bend. When a PCB bends, the bending PCB surface distorts the outer lead bond interface, e.g., the package PCB footprint, from its normal planar condition. Since the lead exit/attach points on the package body remain rigid, the leadframe must absorb all of the distortion in the outer lead bond interface. Depending upon the shape of the distortion induced into the outer lead bond interface, the amount of lead flexure varies with lead position on the package. For a rectangular package, lead flexure is greatest on leads with exit or attach points furthest from the package center. The larger this distance, e.g., the larger the package, the greater the lead flexure. Leads with the highest flexure are the first to fail. So, there is a need for package designs that reduce lead failure due to repeated lead flexure caused by acceleration, shock and vibration.

In addition to minimizing lead failure, there is also a need for package designs that reduce the size and weight of packages. As electronic systems become more complex and electronic devices become smaller, there is a continual need to fit more packages in smaller areas without increasing the weight of the electronic devices. This need can be met by reducing the size and weight of each package. So, there is an ongoing need for package designs that reduce the size and weight of packages.

### SUMMARY

There is a need for electronic package designs that reduce lead failure due to repeated lead flexure caused by acceleration, shock and vibration. There is also a need for electronic package designs of reduced size and weight. An electronic package with a stepped-pitch leadframe steps from a lesser pitch where the leadframe exits or attaches to the package body to a greater pitch at the outer lead bond where the leadframe terminates for external connections, e.g., the SMT pads or through-holes of its PCB footprint. In an electronic package with a stepped-pitch leadframe, leads are less likely to fail under acceleration, shock and vibration. An electronic package with a stepped-pitch leadframe also offers the advantages of reduced package body and PCB footprint size and weight.

In one embodiment, a leadframe for an electronic package is provided. The lead frame includes a plurality of leads each having an outer lead bond and an inner lead bond. The plurality of leads are interconnected by a tie bar. The plurality of leads have a first pitch at an exit or attach point for an electronic package and a second, larger pitch at the outer lead bonds.

### BRIEF DESCRIPTION OF THE DRAWINGS

FIG. 1 is a perspective view of one embodiment of an electronic package with a stepped-pitch, side-exit leadframe on a PCB.

FIG. 2 is a top view of the embodiment of the electronic package of FIG. 1.

FIG. 3 is a side view of the embodiment of the electronic package of FIG. 1.

FIG. 4 is a side view of the embodiment of the electronic package of FIG. 1 on a bending PCB.

FIG. 5 is a perspective view of another embodiment of an electronic package with a stepped-pitch, external-attach leadframe on a PCB.

FIGS. 6 through 10 is a series of views that illustrate one embodiment of a method for manufacturing an electronic package with a stepped-pitch leadframe.

FIG. 11 shows one embodiment of an external attach leadframe.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense.

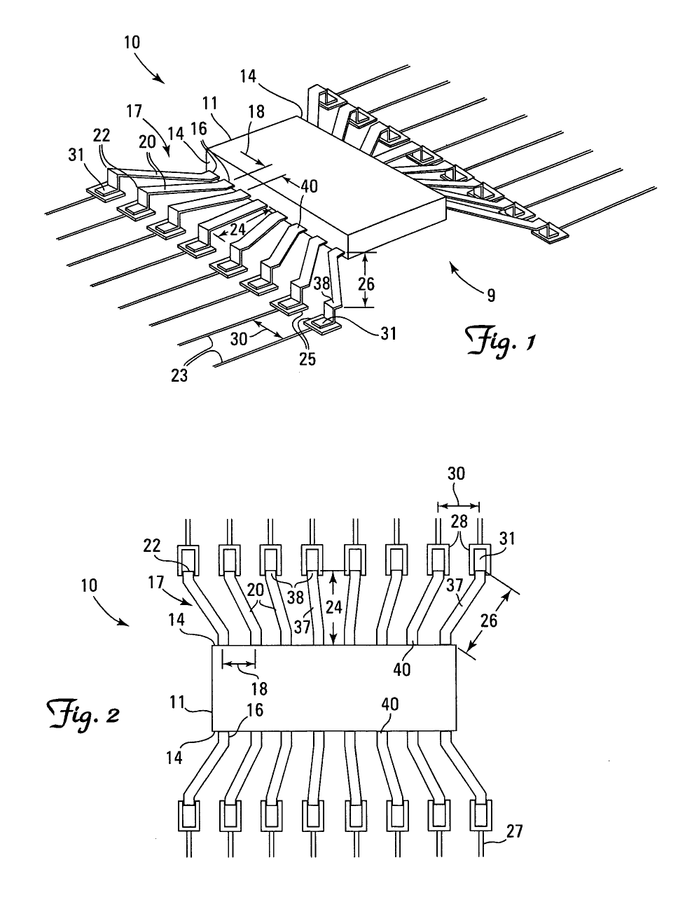

FIG. 1 shows a perspective view of one embodiment of an electronic package, indicated generally at 10, with a stepped-pitch, side-exit leadframe 17 on a printed circuit board (PCB) 9. In this embodiment, electronic package 10 is a dual flat package (DFP) because leads exit from two sides 14 of package body 11. In other embodiments, electronic package 10 is a quad flat package or other appropriate configuration of leads exiting from package body 11.

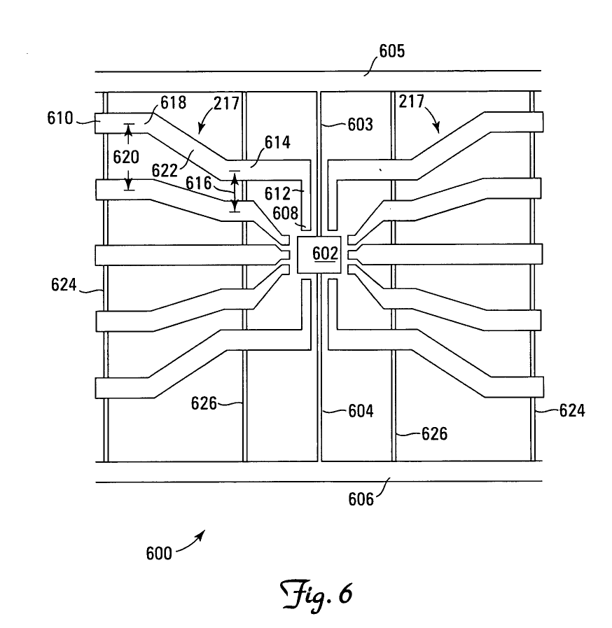

Leadframe 17 of electronic package 10 has leads 20 with a stepped-pitch to reduce lead failure under acceleration, shock and vibration and to reduce the size of package body 11 and the footprint size on PCB 9. “Stepped-pitch” means that the pitch 18 (also referred to as “exit pitch”) of leads 20 at exit point 16 from package body 11 is less than the pitch 30 (also referred to as “connection pitch” or “outer lead bond pitch”) of outer lead bonds 31. It is noted that for the side-exit leadframe, the pitch of its inner lead bond (see FIG. 6) at the die is typically much less than its side exit pitch 18.

Generally, the minimum package PCB footprint size is determined by the size of the package body 11 plus the minimum formed lead length distance from the lead exit/attach point 16 on the package body 11 to the outer lead bond 31 necessary for sufficient lead compliance flexibility to meet system reliability requirements. Lead compliance is proportional to the formed length of the lead 20. As the exit pitch 18 at the package is reduced to less than the connection pitch 30 at the outer lead bond, the formed lead length varies with lead position on the package such that those leads furthest from the package center have the longest formed lead length, e.g., as indicated by the relative lengths indicated at 24 and 26, and the greatest lead compliance where it's needed the most. The combination of reduced pitch at the exit point 16 and variable formed lead length enable both reduced package body size and PCB footprint size while still providing the necessary lead compliance to meet system reliability requirements.

Each side 14 of package body 11 is parallel to each row of external connections or outer lead bond pads 28. Bond pads 28 connect to traces 27 on PCB 9. In a typical side-exit package, all leads exit package body 11 perpendicular (at 90°) to each side 14 and are the same length, which in this case, is the perpendicular distance between the package side 14 and outer lead bond pads 28. Lead length is driven by the minimum compliance needed in leads with the greatest deflection (e.g. the corner leads). In the stepped-pitch lead frame, the angle between each angled lead segment and each side 14 varies from perpendicular (90°) at the center to the smallest inside angle at the ends. When angled, the compliance lead length can be greater than the perpendicular distance between the package side 14 and the outer lead bonds 31. Because of this, the same corner lead compliance length is available with less perpendicular distance between package side 14 and outer lead bond pads 28. So, for the same package body width, a standard leadframe package requires a wider PCB footprint than a stepped-pitch leadframe package to get the same corner lead compliance. Also, because of its smaller exit pitch 18, the package body 11 using a stepped-pitch leadframe 17 can be shorter than the body of a package using a standard leadframe. The smaller size of package body 11 results in a smaller package weight. Inside package body 11, but not shown, each lead 20 is electrically connected to at least one integrated circuit (IC) die.

Side-exit leadframe 17 is made up of leads 20. Each lead 20 exits side 14 of body 11 at side-exit point 16. The spacing of adjacent leads 20 at their side-exit points 16 defines exit pitch 18. Each lead 20 exits body 11 at 90 degrees to the side 14 and then forms an angle, relative to the normal of side 14 of package body 11. This angled portion of lead 20 is referred to as its angled segment 37. Leads 20 have various lengths when each lead length is measured from side-exit point 16 to first lead bend 22. Leads 20 in the middle of side of body 14 have middle lead length 24. Leads 20 at the ends of side of body 14 have end lead length 26. End lead length 26 is longer than middle lead length 24. The longer end lead length 26 allows for greater deflection of lead 20 at the ends of side 14 of package body 11 where the maximum deflection of lead 20 typically occurs. As a result, leads 20 are less likely to fail under acceleration, shock and vibration.

As seen in FIG. 2, each lead 20 also has a first parallel segment 38 and a second parallel segment 40 at either end of angled segment 37. The first parallel segment 38 of each lead 20 is parallel to the parallel segment 38 of each of the other leads 20. Similarly, the second parallel segment 40 of each lead 20 is parallel to the parallel segment 40 of each of the other leads 20. First parallel segment 38 travels a distance out from angled segment 37 to first lead bend 22 and down to external connection 28 at outer lead bond 31. The spacing of adjacent external connections 28 defines outer lead bond pitch 30. Second parallel segments 40 defines exit pitch 18. Exit pitch 18 is less than outer lead bond pitch 30. Side-exit leadframe 17 steps exit pitch 18 up to outer lead bond pitch 30 with angled sections 37 of leads 20 of varied lengths.

Returning to FIG. 1, the small portion of the first parallel segment 38 of each lead adjacent to its downward bend point is at 90° relative to the bend line. In the manufacturing process, the leadframe 17 is clamped inside the downward bend points 22 as the outer portion of parallel segment 38 of the leadframe 17 is formed down, outward and sheared to length. This clamping protects the package lead exit/attach points from stress during the lead forming and shearing operation. The small portion of the parallel segment 38 adjacent to the downward bend insures straight downward and outward lead bends during the forming and shearing operation. If the unformed leads 20 do not cross the bend point 22 at 90°, then the resulting downward and outward bends will not be straight.

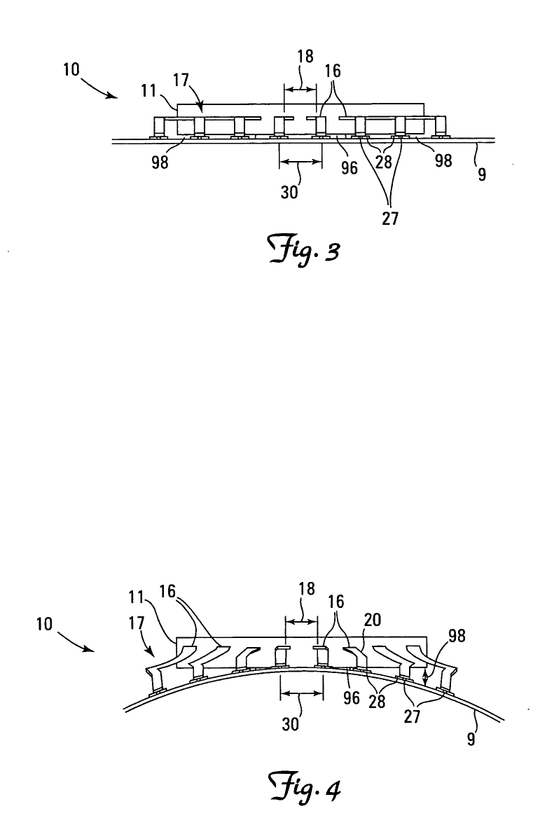

As shown in FIG. 3, package body 11 is separated from PCB 9 by gap 98. Package body adhesive 96 in gap 98 bonds package body 11 to PCB 9.

FIG. 4 shows an electronic package 10 on PCB 9 when PCB 9 is bending as it might bend under acceleration, shock and vibration. The bending of PCB 9 causes the surface of PCB 9 to separate away from body 11 and causes increased gap 98. Advantageously, the stepped-pitch lead frame 17 reduces the risk of lead failure when PCB 9 bends such as shown in FIG. 4 because longer leads 20 are used at the extremes of the body 11 of electronic package 10. Further, the stepped-pitch lead frame 17 also allows a smaller package body 11 to be used thereby reducing the size and weight of electronic package 10. The smaller PCB footprint spans a smaller portion of the PCB flexure, resulting in less lead flexure.

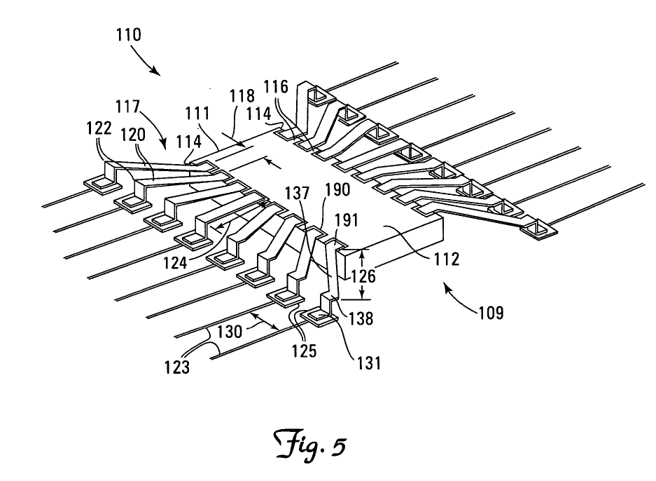

A stepped-pitch leadframe can also be used with a variety of package forms. The stepped-pitch leadframe can be used with packages of various shapes, including rectangular packages. The stepped-pitch leadframe can be used with various body materials, including ceramic and plastic. The stepped-pitch leadframe can be can be used with various lead configurations, including DFP packages and QFP packages. The stepped-pitch leadframe can be used with various numbers of leads. The stepped-pitch leadframe can be used with various leadframe types, including side-exit leadframes, such as shown and described above with respect to FIGS. 1-4, and external attach leadframes such as shown and described below with respect to FIG. 5.

FIG. 5 shows a perspective view of another embodiment of an electronic package, indicated generally at 110, with a stepped-pitch external attach leadframe 117 on a printed circuit board (PCB) 109. In this embodiment, electronic package 110 is a DFP package because leads 120 extend from two sides 114 of package body 111. In other embodiments, electronic package 110 is a QFP package or other appropriate configuration of leads extending from package body 111.

Leadframe 117 of electronic package 110 has leads 120 with a stepped-pitch to reduce lead failure under acceleration, shock and vibration and to reduce the size of package body 111 and the footprint size on PCB 109. As with the embodiment of FIG. 1, “stepped-pitch” means that the pitch 118 (also referred to as “attach pitch” or inner lead bond pitch) of leads 120 at attach point 116 of leadframe 117 is less than the pitch 130 (also referred to as “connection pitch” or “outer lead bond pitch”) of outer lead bonds 131.

External attach leadframe 117 is made up of leads 120. Each lead 120 attaches to a lead attach pad 190 on surface 112 of body 111 at attach points 116. The spacing of adjacent leads 120 at their attach points 116 defines attach pitch 118. Each lead 120 attaches to lead attach pad 190 on surface 112 of package body 111 and extends at an angle, relative to the normal of side 114 of package body 111. The portion of lead 120 that attaches to the lead attach pad 190 is referred to as a first parallel segment 191. Parallel segments 191 of the various leads 120 are parallel to each other. An angled segment 137 of lead 120 extends from first parallel segment 191. Leads 120 have various lengths when each lead length is measured from attach point 116 to first lead bend 122. Leads 120 in the middle of side 114 of body 111 have middle lead length 124. Leads 120 at the ends of side 114 of body 111 have end lead length 126. End lead length 126 is longer than middle lead length 124. The longer end lead length 126 allows for greater deflection of lead 120 at the ends of side 114 of package body 111 where the maximum deflection of lead 120 typically occurs. As a result, leads 120 are less likely to fail under acceleration, shock and vibration.

Each lead 120 also has a second parallel segment 138. The second parallel segment 138 of each lead 120 is parallel to the second parallel segment 138 of each of the other leads 120. Second parallel segment 138 travels a distance out from angled segment 137 to first lead bend 122 and down to external connection 128 at outer lead bond 131. The spacing of adjacent external connections 128 defines outer lead bond pitch 130. Attach pitch 118 is less than outer lead bond pitch 130. External attach leadframe 117 steps attach pitch 118 up to outer lead bond pitch 130 with angled sections 137 of leads 120 of varied lengths.

The small portion of the second parallel segment 138 of each lead adjacent to its downward bend point is at 90° relative to the bend line. In the manufacturing process, the leadframe 117 is clamped inside the downward bend points 122 as the outer portion of parallel segment 138 of the leadframe 117 is formed down, outward and sheared to length. This clamping protects the package lead attach points from stress during the lead forming and shearing operation. The small portion of the second parallel segment 138 adjacent to the downward bend insures straight downward and outward lead bends during the forming and shearing operation. If the unformed leads 120 do not cross the bend line at 90°, then the resulting downward and outward bends will not be straight.

FIGS. 6 through 10 illustrate one embodiment of a process for fabricating an electronic package with a stepped-pitch leadframe. This process is illustrated herein by way of example and not by way of limitation. Other processes, existing or later developed, can be used to incorporate a stepped pitch leadframe into an electronic package. One advantage of the stepped-pith leadframe as shown in the illustrative embodiments of this application is that the leadframe can be incorporated into an electronic package without changing the basic process flow.

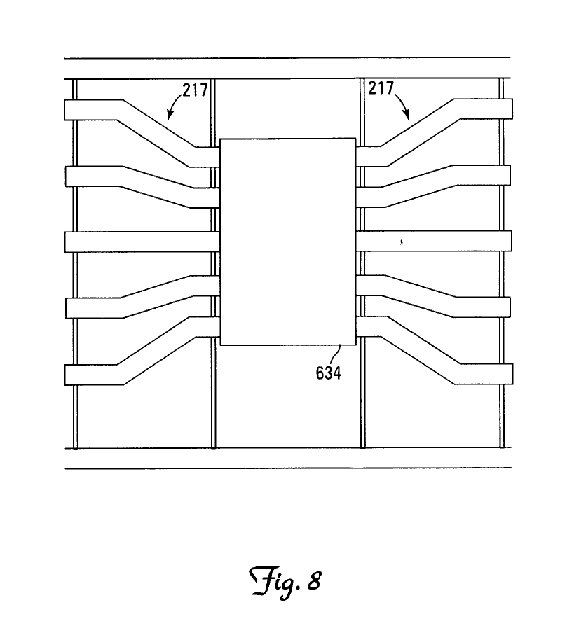

As shown in FIG. 6, the process begins with a stepped-pitch leadframe 600. Leadframe 600 includes die attach pad 602. Die attach pad 602 is held in place by connectors 603 and 604 that provide connection to tie bars 605 and 606, respectively. A plurality of leads, indicated generally at 217 extend from, but do not connect to, the perimeter on die attach pad 602. In this embodiment, leadframe 600 is a DFP leadframe. In other embodiments, leads 217 may be laid out for use in a QFP or other appropriate configuration. Each lead 217 includes an inner lead bond 608 and an outer lead bond 610. Each lead 217 also includes a first portion 612 that extends from inner lead bond 608 to a first parallel segment 614. The first parallel segments 614 define the exit pitch 616 at the point where leads 217 exit the side of the package body as shown in FIG. 8 and described in more detail below. Each lead 217 also includes a second parallel portion 618 that defines a connection pitch 620 that is greater than the exit pitch 618. First and second parallel segments 614 and 618 are coupled together by angled segment 622. The length of angled segments 622 vary from lead to lead with the shortest segment in the center of leadframe 600 and the longest length at the ends of leadframe 600.

Leads 217 are held in place during the fabrication process using, for example, tie bars 624 and 626. Other arrangements of tie bars can also be used. Outer tie bars 624 hold the outer lead bonds in place while inner tie bars 626 hold the leads 217 in place adjacent to the exit point of the package.

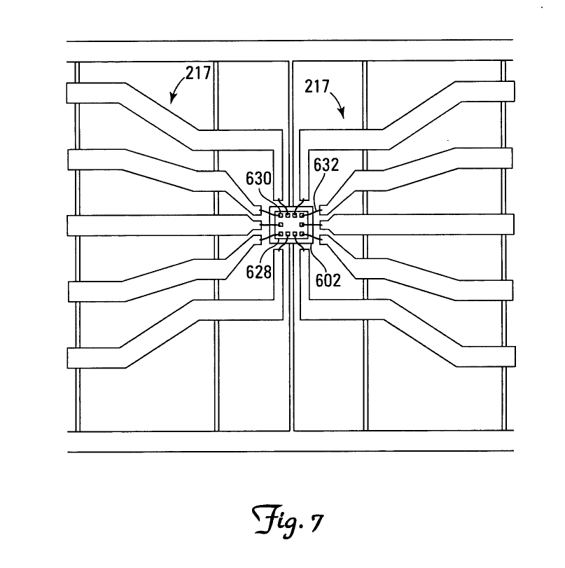

As shown in FIG. 7, at least one integrated circuit (IC) die 628 is placed on the die attach pad 602. In other embodiments, multiple independent integrated circuit dice are attached to die attach pad 602. The single integrated circuit die 628 is shown by way of example and not by way of limitation. In one embodiment, integrated circuit die 628 is bonded, e.g., glued (or soldered), to die attach pad 602. Leads 217 are coupled to bond pads 630 via bond wires 632. Bond wires 632 provide electrical connection between the leads 217 and the integrated circuit die 628. The assembly of the lead frame 600 and integrated circuit die 628 is covered by a package body 634, e.g., a plastic or ceramic body, as shown in FIG. 8.

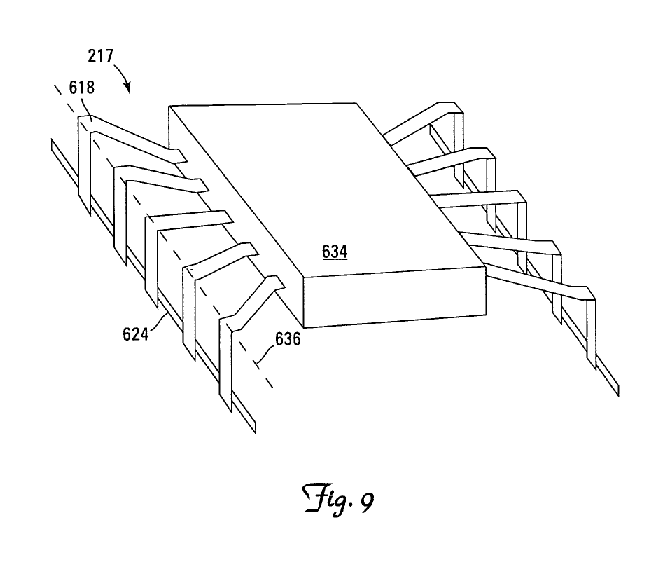

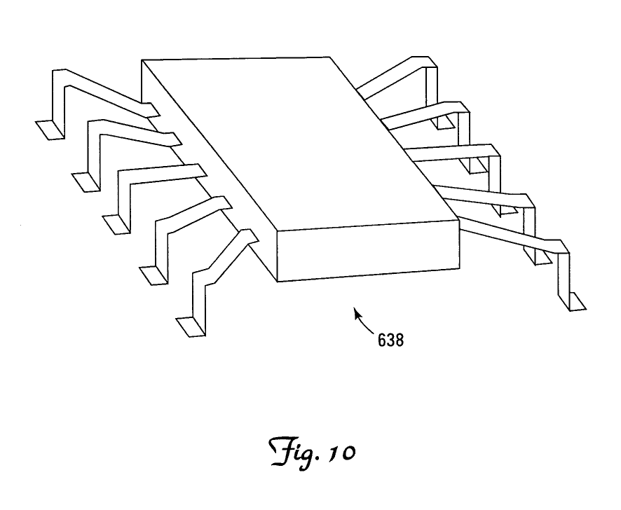

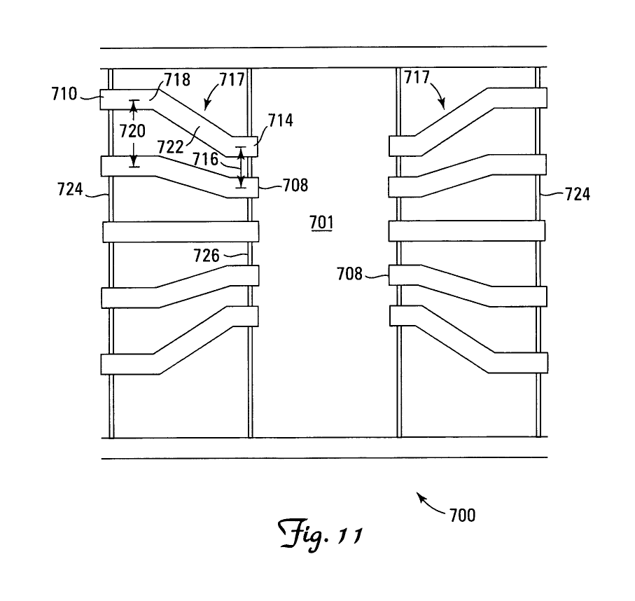

Once enclosed, the inner lead tie bar 626 is removed and the leads 217 are formed into final position by bending and shearing to length. An initial 90 degree bend is applied to parallel portion 618 by clamping the leads 217 on one side of package body 634 together along a clamp line 636 as shown in FIG. 9. As further shown in FIG. 10, electronic package 638 is completed by applying a second 90 degree bend to parallel portion 618 at outer lead bond 610. Outer tie bar 624 is also removed when the parallel portions 618 are cut to length.

FIG. 11 shows one embodiment of an external attach leadframe, indicated generally at 700. Leadframe 700 includes a plurality of leads, indicated generally at 717. Leads 717 extend from a center 701 of leadframe 700. In this embodiment, leadframe 700 is a DFP leadframe. In other embodiments, leads 717 may be laid out for use in a QFP or other appropriate configuration. Each lead 717 includes an inner lead bond 708 and an outer lead bond 710. Each lead 717 also includes a first parallel segment 714. The first parallel segments 714 define the attach pitch 716 at the point where leads 717 attach to the exterior side, top or bottom of the package body. Each lead 717 also includes a second parallel portion 718 that defines a connection pitch 720 that is greater than the attach pitch 718. First and second parallel segments 714 and 718 are coupled together by angled segment 722. The length of angled segments 722 vary from lead to lead with the shortest segment in the center of leadframe 700 and the longest length at the ends of leadframe 700.

Leads 717 are held in place during the fabrication process using, for example, tie bars 724 and 726. Other arrangements of tie bars can also be used. Outer tie bars 724 hold the outer lead bonds in place while inner tie bars 726 hold the leads 717 in place adjacent to the exterior attach points of the package.

The external attach leadframe 700 is fabricated into an electronic package in a manner similar to the process described above with respect to FIGS. 6-10 with the leads 717 attaching to pads on the external surface of an integrated circuit package.

Although the present invention has been described with reference to specific embodiments, workers skilled in the art will recognize that changes may be made in form and detail without departing from the spirit and scope of the invention. For example, other configurations of tie bars and die attach pads may be used with the stepped-pitch lead frame. Further, the outer lead bonds may be bent at an angle other than exactly 90 degrees. Further, the relative lengths of the various segments of the leads in the stepped-pitch leadframe may be varied to accommodate the requirements of a particular circuit. In other embodiments, other conventional or later developed package bodies may be used in place of the plastic or ceramic package bodies described herein.

1-4. (canceled)

5. An electronic package, comprising:
a package body; and
a leadframe provided with the package body, the leadframe comprising:
a plurality of leads;
the plurality of leads includes a first pitch at an exit or attach point for the package body;
the plurality of leads terminates outside the body at an outer lead bond at second pitch; and
the first pitch is less than the second pitch.

6. The package of claim 5, wherein the footprint of the body is rectangular.

7. The package of claim 5, wherein the package is one of a dual flat package and a quad flat package.

8. The package of claim 5, wherein the leadframe is one of a side-exit leadframe and an external attach leadframe.

9. The package of claim 5, wherein the package body comprises one of plastic and ceramic.

10. An electronic package, comprising:
at least one IC die;
a package body housing at least one IC die; and
a leadframe coupled to the at least one IC die, wherein;
a plurality of leads coupled to the at least one IC die;
the plurality of leads includes a first pitch at an exit or attach point for the package body;
the plurality of leads terminates outside the body at an outer lead bond at second pitch; and
the first pitch is less than the second pitch.

11. The package of claim 10, wherein the footprint of the body is rectangular.

12. The package of claim 10, wherein the package is one of a dual flat package and a quad flat package.

13. The package of claim 10, wherein the leadframe is one of a side-exit leadframe and an external attach leadframe.

14. The package of claim 10, wherein the package body comprises one of plastic and ceramic.

15. A flat integrated circuit package, comprising:
at least one semiconductor die;
a package body housing the at least one semiconductor die; and
a side-exit leadframe coupled to the at least one semiconductor die, wherein;
the leadframe includes a plurality of leads;
the plurality of leads exits a side of the package body at an exit pitch;
the plurality of leads terminates outside the body at an outer lead bond pitch; and
the exit pitch is less than the outer lead bond pitch.

16. The flat integrated circuit package of claim 15, wherein each of the plurality of leads includes:
a first parallel segment extending from the exit in the side of the package body;
an angled segment, terminating at the first parallel segment; and
a second parallel segment, extending from the angled segment and terminating at the outer lead bond, the first and second parallel segments being parallel with the first and second parallel segments of the other leads.

17. A flat integrated circuit package, comprising:
at least one semiconductor die;
a package body, housing the at least one semiconductor die, the package body includes a plurality of lead attach pads at a pad pitch; and
an external attach leadframe, wherein;
the leadframe includes a plurality of leads;
the plurality of leads each include an inner lead bond that attach to respective ones of the plurality of lead attach pads at the pad pitch;
the plurality of leads each include an outer lead bond that terminates outside the periphery of the package body at an outer lead bond pitch; and
the pad pitch is less than the outer lead bond pitch.

18. The flat integrated circuit package of claim 17, wherein each of the plurality of leads includes:
a first parallel segment beginning at the inner lead bond and running parallel with the first parallel segment of each of the other leads;
an angled segment, extending from the first parallel segment; and
a second parallel segment, extending from the angled segment.

19-20. (canceled)
